(19) United States
(12) Patent Application Publication
(10) Pub. No.: US 2026/0101450 A1
(43) Pub. Date: Apr. 9, 2026

(54) ELECTRONIC EQUIPMENT

(71) Applicant: CANON KABUSHIKI KAISHA, Tokyo (JP)

(72) Inventors: YASUHITO TATARA, Kanagawa (JP); MAKOTO AOKI, Tokyo (JP); KENJI FUKUSHI, Chiba (JP); TAKUYA UEMURA, Chiba (JP); MINORU AKAZAWA, Chiba (JP)

(21) Appl. No.: 19/348,378

(22) Filed: Oct. 2, 2025

(30) Foreign Application Priority Data
Oct. 8, 2024 (JP) 2024-176757
Sep. 11, 2025 (JP) 2025-150971

(51) Int. Cl. H05K 5/00

(52) U.S. Cl. CPC H05K 5/0069; H05K 5/0018

(57) ABSTRACT

Electronic equipment includes an enclosure made of resin, a wiring board arranged inside the enclosure, and a conductive member arranged inside the enclosure. The conductive member includes a portion arranged between a gap of the enclosure and the wiring board. The portion includes a first portion with one end in a first direction formed as an open end, and a second portion that is continuous with another end in the first direction of the first portion. At least part of the second portion faces the first portion via an insulator in a second direction intersecting with the first direction. A first distance that is a shortest distance between the gap of the enclosure and the first portion is less than a second distance that is a shortest distance between the gap of the enclosure and the second portion.

### BACKGROUND

### Field of the Technology

This disclosure relates to electronic equipment.

### Description of the Related Art

For reasons such as weight reduction or design considerations, electronic equipment provided with resin enclosures is known. Gaps are present at various locations in the enclosures. If static electricity penetrates inside the enclosures through those gaps, there is a risk that the static electricity may be discharged onto wiring patterns of wiring boards arranged adjacent to the gaps, and thereby causes malfunction or breakage to integrated circuits (ICs) connected to the wiring patterns. Japanese Patent Laid-Open No. H05-327259 discloses a configuration in which a grounded conductive linear member is arranged adjacent to a gap of an enclosure.

However, even with the configuration disclosed in Japanese Patent Laid-Open No. H05-327259, there is a risk of a noise superposition resulting from electrostatic discharge onto a wiring board, and, therefore, further improvements are required.

### SUMMARY

This disclosure provides a technique for improving resistance to electrostatic discharge.

According to one aspect of the present disclosure, electronic equipment includes an enclosure made of resin, a wiring board arranged inside the enclosure, and a conductive member arranged inside the enclosure. The conductive member includes a portion arranged between a gap of the enclosure and the wiring board. The portion includes a first portion with one end in a first direction formed as an open end, and a second portion that is continuous with another end in the first direction of the first portion. At least part of the second portion faces the first portion via an insulator in a second direction intersecting with the first direction. A first distance that is a shortest distance between the gap of the enclosure and the first portion is less than a second distance that is a shortest distance between the gap of the enclosure and the second portion.

Features of the present disclosure will become apparent from the following description of embodiments with reference to the attached drawings. The following description of embodiments is described by way of example.

### BRIEF DESCRIPTION OF THE DRAWINGS

FIG. 1A is a perspective view illustrating electronic equipment according to a first embodiment.

FIG. 1B is a cross-sectional view illustrating part of the electronic equipment according to the first embodiment.

FIG. 2A is an explanatory diagram illustrating an area adjacent to a shielding portion of an operation unit according to the first embodiment.

FIG. 2B is an explanatory diagram illustrating the area adjacent to the shielding portion of the operation unit according to the first embodiment.

FIG. 3 is an explanatory diagram illustrating an electrostatic discharge test with respect to the operation unit according to the first embodiment.

FIG. 4 is a cross-sectional view illustrating part of electronic equipment according to a second embodiment.

FIG. 5 is a cross-sectional view illustrating part of electronic equipment according to a third embodiment.

FIG. 6 is a cross-sectional view illustrating part of electronic equipment of a comparative example.

FIG. 7 is a graph illustrating experimental results of Example 1 and the comparative example.

### DESCRIPTION OF THE EMBODIMENTS

Hereinafter, with reference to drawings, embodiments of this disclosure will be described in detail. To be noted, in each drawing, the same reference characters are applied to identical members, and duplicate descriptions will be omitted.

### First Embodiment

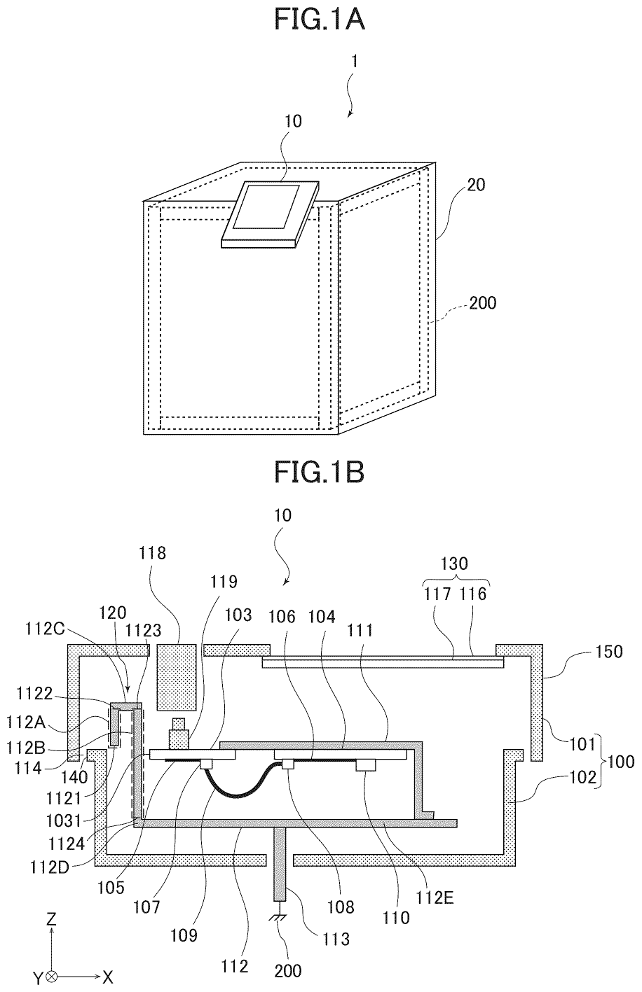

FIG. 1 is a perspective view illustrating electronic equipment 1 according to a first embodiment. Hereinafter, the electronic equipment 1, serving as an electronic apparatus, will be described as, for example, office equipment, specifically an image forming apparatus such as a printer, a copier, or an integrated machine. The electronic equipment 1 includes an actuation unit 20 and an operation unit 10 disposed in the actuation unit 20. The operation unit 10 is disposed to operate the actuation unit 20. In the first embodiment, the actuation unit 20 is the image forming apparatus, and forms an image on a sheet such as paper. The actuation unit 20 includes an enclosure and a metallic frame 200 arranged inside the enclosure. The frame 200 is a metallic casing of the actuation unit 20.

FIG. 1B is a cross-sectional view illustrating part of the electronic equipment 1 according to the first embodiment. In FIG. 1B, a cross-section of the operation unit 10, serving as a part of the electronic equipment 1, is illustrated.

In the following description of the operation unit 10, directions are indicated based on an XYZ coordinate system. The X, Y, and Z axes intersect with each other. The X, Y, and Z axes can intersect orthogonally to each other. The XYZ coordinate system can be an orthogonal coordinate system. In addition, directions of the X, Y and Z axes are also respectively referred to as X, Y, and Z directions. In addition, for example, when indicating the positive direction of the X-axis, it refers to the same direction as that indicated by an X axis arrow in the illustrated coordinate system, and when indicating the negative direction of the X-axis, it refers to a direction that is 180 degrees opposite to that indicated by the X-axis arrow in the illustrated coordinate system. In addition, when simply referring to the X direction, it refers to any direction parallel to the X-axis, regardless of whether it aligns with the illustrated X-axis arrow. The same applies also to the Y and Z axes in addition to the X-axis. In addition, a virtual plane including both the X and Y axes is referred to as an XY plane.

The operation unit 10 includes a resin enclosure 100. The enclosure 100 includes an upper cover 101 and a lower cover 102. The lower cover 102 is an example of a first cover, and the upper cover 101 is an example of a second cover. The lower cover 102 includes a bottom plate portion and a side wall portion that extends in the positive direction of the Z-axis with respect to the bottom plate portion. The upper cover 101 includes a top plate portion and a side wall portion that extends in the negative direction of the Z-axis with respect to the top plate portion. A side wall 150 of the enclosure 100 is formed by engaging the side wall portions of the upper and lower covers 101 and 102.

In addition, the operation unit 10 is provided with a touch panel display 130 including a touch panel 116 and a liquid crystal display 117, a button 118, wiring boards 103 and 104, and a conductive member 112. The touch panel display 130 and the button 118 are secured to the top plate portion of the upper cover 101. The wiring boards 103 and 104 and the conductive member 112 are arranged inside the enclosure 100. The touch panel display 130 may be electrically connected to either of the wiring board 103 or 104, or the touch panel display 130 may be electrically connected to the actuation unit 20.

Here, a direction orthogonal to a touch surface (main surface) of the touch panel display 130 is referred to as the Z direction. The Z direction is also a height direction of the side wall 150 of the enclosure 100. In addition, the Z direction is also a direction orthogonal to a main surface of the wiring board 103. The Z direction is an example of a first direction. The X direction is an example of a second direction. The Y direction is an example of a third direction.

A switch 119 and a connector 107 are mounted to the wiring board 103. An integrated circuit (IC) 110 and a connector 108 are mounted to the wiring board 104. One end of a cable 109 is connected to the connector 107, and the other end of the cable 109 is connected to the connector 108. Thereby, the wiring boards 103 and 104 are electrically connected via the cable 109. A wiring pattern 105 that electrically connects the switch 119 and the connector 107 is arranged on the wiring board 103, and a wiring pattern 106 that electrically connects the IC 110 and the connector 108 is arranged on the wiring board 104. Each of the wiring boards 103 and 104 is a wiring board having a rectangular shape when viewed in the Z direction, that is, in plan view.

The switch 119 faces the button 118 in the Z direction. The switch 119 is, for example, a tact switch, and, when the button 118 is pressed by a user, the button 118 comes into contact with the switch 119, and the switch 119 transitions to an ON state. In addition, when the user lifts a finger from the button 118, the button 118 disengages from the switch 119, and the switch 119 transitions to an OFF state.

Through the wiring pattern 105 of the wiring board 103, the connector 107, the cable 109, the connector 108, and the wiring pattern 106 of the wiring board 104, an ON/OFF signal of the switch 119 is transmitted to the IC 110, and, thereby, the ON/OFF state of the switch 119 is read by the IC 110. To be noted, the IC 110 may be configured to control the touch panel display 130.

The wiring boards 103 and 104 are secured to a conductive fixed plate 111 with screws or the like. Thereby, ground patterns, not shown, of the wiring boards 103 and 104 are electrically connected to the fixed plate 111. The fixed plate 111 is secured to the conductive member 112 with screws or the like. Thereby the fixed plate 111 is electrically connected to the conductive member 112.

The conductive member 112 is connected to the metallic frame 200 of the actuation unit 20 via a grounding member 113. Thereby, the conductive member 112 and the ground patterns of the wiring boards 103 and 104 are electrically connected to the frame 200. The frame 200 is grounded to earth via an earth wire or the like.

To be noted, while, in the first embodiment, the fixed plate 111 and the conductive member 112 are separate members and connected with screws or the like, it is not limited to this, and, for example, the fixed plate 111 and the conductive member 112 may be integrally formed from a single metal plate. In addition, while, in this embodiment, the grounding member 113 is also configured as a separate member from the fixed plate 111 and the conductive member 112, the grounding member 113 may similarly be integrally formed from a single metal plate. To be noted, the conductive member 112 may be a metal sheet or a member such as a film formed by plating on a surface of a resin member (not shown), instead of the metal plate. In addition, the conductive member 112 is not limited to a metal member. For example, the conductive member 112 may be a conductive member such as a conductive carbon sheet or a conductive resin member.

The lower cover 102 is secured to at least the conductive member 112 with screws or the like. The conductive member 112 is secured to the frame 200 via the grounding member 113. The upper cover 101 is secured to the lower cover 102 by engaging with the lower cover 102. Due to manufacturing tolerances and the like of the operation unit 10, a gap 114 is formed along an outer periphery of the enclosure 100 between the side wall portions of the lower and upper covers 102 and 101. As described above, in the first embodiment, the gap 114 is formed in the side wall 150 of the enclosure 100.

To be noted, besides the gap 114, in the enclosure 100, gaps are present around other components, such as, for example, the touch panel display 130, the button 118, and a light emitting diode (LED), not shown; however, this description will focus on the gap 114, which is located closest to the wiring board 103.

The conductive member 112 is formed by a bending process of a metal plate. In the first embodiment, the conductive member 112 includes a base portion 112E and a shielding portion 120. The shielding portion 120 is continuous with the base portion 112E.

The base portion 112E is, for example, formed in a flat plate shape parallel to the XY plane. To be noted, the base portion 112E may include irregularities or through-holes. The base portion 112E faces the main surface (mounting surface) of each of the wiring boards 103 and 104 in the Z direction. The shielding portion 120 is continuous with an end portion in the negative direction of the X-axis of the base portion 112E via a bent portion 112D. The grounding member 113 is connected to a substantially center area of the base portion 112E. The bent portion 112D is, for example, formed by a bending process. That is, the shielding portion 120 is bent at the bent portion 112D in the positive direction of the Z-axis with respect to the base portion 112E.

The shielding portion 120 is arranged between the gap 114 and the wiring board 103 in the X direction. In the X direction, an edge surface 1031, which is one of four edge surfaces of the wiring board 103, faces toward a side of the shielding portion 120. The edge surface 1031 extends in the Y direction, with the Z direction serving as a short direction and the Y direction serving as a longitudinal direction. The short direction of the edge surface 1031 is also a thickness direction of the wiring board 103, and the longitudinal direction of the edge surface 1031 is also a width direction of the wiring board 103.

During an electrostatic discharge (air discharge) test with respect to the operation unit 10, in a case where a charged probe such as a metallic rod is brought close to the gap 114 from an exterior of the enclosure 100, static electricity is discharged from the probe toward the gap 114. The static electricity discharged to the gap 114 flows along a delineated surface 140, which defines the gap 114, of the enclosure 100, and propagates into an inner space of the enclosure 100. The static electricity which has penetrated the inner space of the enclosure 100 via the gap 114 is discharged to the shielding portion 120, and thereby discharge to the wiring board 103 is suppressed. That is, the shielding portion 120 serves to block the static electricity from being directly discharged from the gap 114 to the wiring board 103. The static electricity discharged to shielding portion 120 flows from the shielding portion 120 to the base portion 112E as an electrical current, and flows from the base portion 112E to ground via the grounding member 113 and the frame 200.

In the first embodiment, the shielding portion 120 includes a first portion 112A and a second portion 112B, and the first and second portions 112A and 112B are arranged in a facing configuration to face each other. At least part of the second portion 112B faces the first portion 112A in the X direction via air which serves as an insulator. In the first embodiment, part of the second portion 112B faces the first portion 112A in the X direction via air which serves as an insulator.

The first and second portions 112A and 112B are connected via a bent portion 112C, and the second portion 112B and the base portion 112E are connected via the bent portion 112D.

One end 1121 in the Z direction of the first portion 112A is formed as an open end, and the other end 1122 in the Z direction is continuous with one end 1123 in the Z direction of the second portion 112B via the bent portion 112C. The other end 1124 in the Z direction of the second portion 112B is continuous with the base portion 112E via the bent portion 112D.

The open end, which is the one end 1121 of the first portion 112A, faces toward the side of the bottom plate portion of the lower cover 102 in the Z direction, and the other end 1122 of the first portion 112A and the one end 1123 of the second portion 112B face toward the side of the top plate portion of the upper cover 101 in the Z direction. The other end 1124 in the Z direction of the second portion 112B faces toward the side of the bottom plate portion of the lower cover 102 in the Z direction. The base portion 112E is arranged between the bottom plate portion of the lower cover 102 and the wiring boards 103 and 104 in the Z direction.

In the X direction, the first portion 112A is arranged on a side of the gap 114 with respect to the second portion 112B, and the second portion 112B is arranged on a side of the wiring board 103 with respect to the first portion 112A. Then, in the X direction, the edge surface 1031 of the wiring board 103 faces the second portion 112B. That is, the second portion 112B overlaps the edge surface 1031 of the wiring board 103 in the X direction.

The shielding portion 120 is formed by folding back a metal plate through one or a plurality (for example, two) of bending processes. That is, the first portion 112A is bent at the bent portion 112C in the negative direction of the Z-axis with respect to the second portion 112B. To be noted, the second portion 112B is bent at the bent portion 112D in the positive direction of the Z-axis with respect to the base portion 112E.

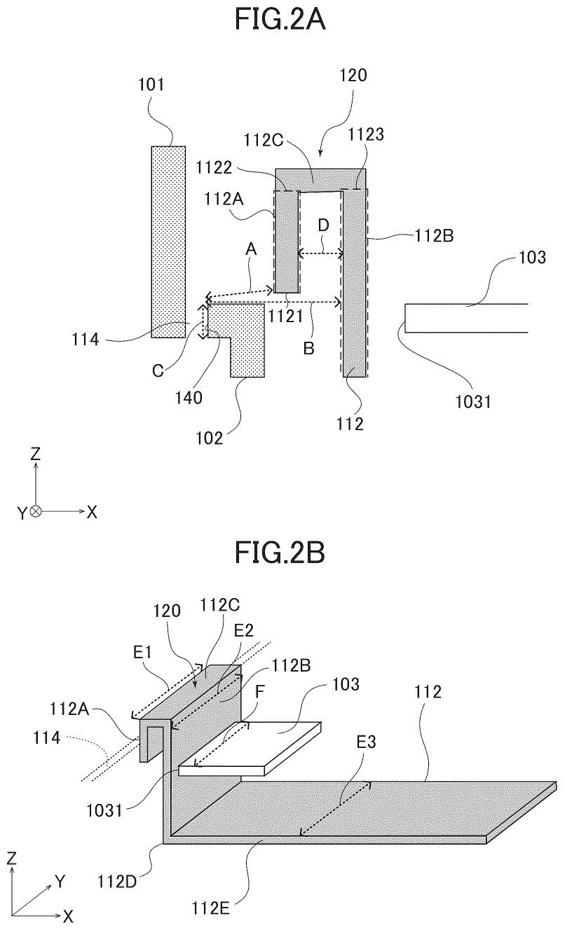

FIGS. 2A and 2B are explanatory diagrams illustrating an area adjacent to the shielding portion 120 of the operation unit 10 according to the first embodiment. FIG. 2A illustrates part of the operation unit 10, in which the operation unit 10 is cut along a virtual plane parallel to the XY plane and viewed in the positive direction of the Y-axis. FIG. 2B is a perspective view illustrating the conductive member 112 of the operation unit 10 and part of its adjacent members.

In the first embodiment, a shortest distance A between the gap 114 and the first portion 112A is less than a shortest distance B between the gap 114 and the second portion 112B. The shortest distance A is an example of a first distance. The shortest distance B is an example of a second distance. That is, the first portion 112A is arranged on the side of the gap 114 with respect to the second portion 112B, and the second portion 112B is arranged on the side of the wiring board 103 with respect to the first portion 112A.

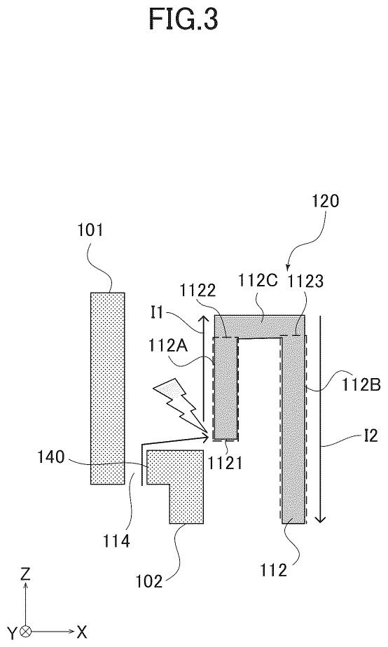

FIG. 3 is an explanatory diagram illustrating the electrostatic discharge test with respect to operation unit 10 according to the first embodiment. When performing the electrostatic discharge (air discharge) test with respect to the operation unit 10 of the electronic equipment 1, the static electricity is discharged to the first portion 112A of the conductive member 112 via the gap 114. The electrical current, which has entered the conductive member 112 due to the electrostatic discharge test, flows to the frame 200 via the grounding member 113. At that time, since, by folding back the first portion 112A at the bent portion 112C, the shielding portion 120 is formed in the facing configuration in which the first and second portions 112A and 112B face each other in the X direction, an electrical current 11 in the first portion 112A due to the static electricity and an electrical current 12 in the second portion 112B due to the static electricity flow in directions opposite to each other. Therefore, a cancellation effect is produced between a magnetic field generated by the electrical current 11 flowing through the first portion 112A and a magnetic field generated by the electrical current 12 flowing through the second portion 112B; thereby, an electrostatic noise superposition, which is caused by electromagnetic coupling from the conductive member 112, onto the wiring pattern 105 of the wiring board 103, which is disposed adjacent to the second portion 112B, is suppressed. In other words, since a voltage level of the electrostatic noise is reduced, the IC 110 is less likely to malfunction or suffer breakage; thereby, the resistance of the operation unit 10 with respect to the electrostatic discharge is enhanced. That is, according to the first embodiment, a technique is provided that improves the resistance with respect to the electrostatic discharge.

At this point, the static electricity discharged into the gap 114 flows along the delineated surface 140 that defines the gap 114. The sum (A+C) of the shortest distance A between the gap 114 and the first portion 112A, and a creeping distance C of the delineated surface 140 that defines the gap 114 can be equal to or less than 12 millimeters (mm). 12 mm is a distance at which, with an insulation breakdown strength of the air set at 1.25 kilovolts (kV)/mm, and when performing electrostatic discharge (air discharge) test at a maximum applied voltage level of 15 kV, discharge to the conductive member 112 can occur. When the sum (A+C) of the shortest distance A and the creeping distance C is equal to or less than 12 mm, the static electricity that has entered from the gap 114 to the inner space of the enclosure 100 becomes likely to be discharged to the first portion 112A of the shielding portion 120.

In addition, a distance D between the first and second portions 112A and 112B in the X direction can be equal to or less than 5.8 mm. When the distance D between the first and second portions 112A and 112B is equal to or less than 5.8 mm, the cancellation effect between the magnetic fields generated by the electrical currents 11 and 12 is enhanced, and, thereby, it is possible to effectively suppress the noise superposition onto the wiring pattern 105 of the wiring board 103. As the distance D decreases, the magnetic field cancellation effect is increasingly enhanced. Accordingly, in some embodiments, the distance D is equal to or less than 5.0 mm. In more particular embodiments, the distance D is equal to or less than 3.4 mm. In addition, considering manufacturing tolerances of the conductive member 112, the distance D can be equal to or greater than 0.1 mm.

In some embodiments, the length E2 of the second portion 112B in the Y direction is greater than the length F of edge surface 1031 of the wiring board 103 in the Y direction. Thereby, when an interior of the enclosure 100 is viewed from the gap 114 in the positive direction of the X-axis, the edge surface 1031 of the wiring board 103 is shielded by the second portion 112B; therefore, it is possible to effectively suppress the direct discharge of the static electricity, which has entered the inner space of the enclosure 100 from the gap 114, to the wiring pattern 105 or the ground pattern of the wiring board 103. In addition, in some embodiments, the length E1 of the first portion 112A in the Y direction is greater than the length F of the edge surface 1031 of the wiring board 103 in the Y direction. Further, the length E1 can be equal to or greater than the length E2. Thereby, the static electricity that has entered the inner space of the enclosure 100 from the gap 114 becomes likely to be discharged to the first portion 112A. In addition, the length E3 of the base portion 112E in the Y direction is greater than the length F of the edge surface 1031 of the wiring board 103 in the Y direction. Thereby, in the Z direction, the base portion 112E can be opposed to the entire main surface of the wiring board 103.

### Second Embodiment

A second embodiment will be described. Hereinafter, elements provided with reference characters common to those in the first embodiment are to be considered to have substantially the same in configuration and function as those described in the first embodiment unless specifically described otherwise, and aspects that differ from the first embodiment will be primarily described.

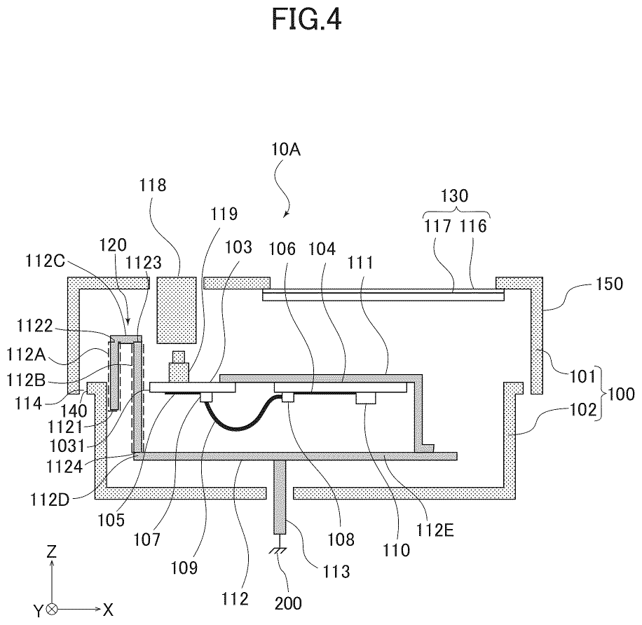

FIG. 4 is a cross-sectional view illustrating part of electronic equipment according to the second embodiment. In FIG. 4, a cross-section of an operation unit 10A, serving as a part of the electronic equipment, is illustrated. In the second embodiment, the length of the first portion 112A of the shielding portion 120 of the conductive member 112 in the Z direction is greater than the length of the first portion 112A of the first embodiment in the Z direction. That is, in the second embodiment, the first portion 112A overlaps the edge surface 1031 of the wiring board 103 in the X direction.

Since, as described above, in the second embodiment, the first portion 112A becomes elongated, the second portion 112B is shielded by the first portion 112A, and becomes unobservable from the gap 114 when viewed in the positive direction of the X-axis; therefore, the static electricity becomes more likely to be discharged to the first portion 112A. In addition, an area in which the first and second portions 112A and 112B face each other increases, and, thereby, the magnetic field cancellation effect is further enhanced. Therefore, it is possible to suppress the noise superposition onto the wiring pattern 105 of the wiring board 103. In other words, the malfunction and breakage of the IC 110 due to the static electricity become less likely to occur, and the resistance to the electrostatic discharge is further enhanced.

### Third Embodiment

A third embodiment will be described. Hereinafter, elements provided with reference characters common to those in the first or second embodiment are to be considered to have substantially the same in configuration and function as those described in the first or second embodiment unless specifically described otherwise, and aspects that differ from the first and second embodiments will be primarily described.

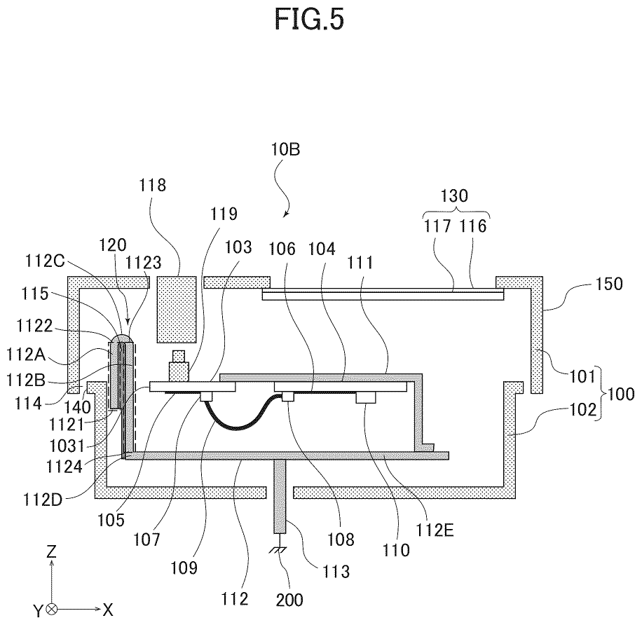

FIG. 5 is a cross-sectional view illustrating part of electronic equipment according to the third embodiment. In FIG. 5, a cross-section of an operation unit 10B, serving as a part of the electronic equipment, is illustrated. In the third embodiment, the insulator between the first and second portions 112A and 112B is an insulating film 115. The insulating film 115 is an example of an insulating member. The insulating film 115 is formed by applying an insulating coating to part of a surface of the conductive member 112 via painting. To be noted, the method for forming the insulating film 115 is not limited to insulating coating; for example, insulating tape or the like may be applied to part of the surface of the conductive member 112.

The conductive member 112 is formed by folding back a metal plate through a U-bend process (hemming bending process) using a press. Even when the metal plate is pressed, the insulating film 115 continues to be present between the first and second portions 112A and 112B. In addition, through pressing, it is possible to reduce the distance D between the first and second portions 112A and 112B. Therefore, the magnetic field cancellation effect is further enhanced, and the noise superposition onto the wiring pattern 105 of the wiring board 103 is further suppressed. In other words, the malfunction and breakage of the IC 110 due to the static electricity become less likely to occur, and the resistance to the electrostatic discharge is further enhanced.

### EXAMPLE

As Example 1, the electrostatic discharge (air discharge) test was conducted with respect to the electronic equipment 1 of the first embodiment illustrated in FIG. 1A, under the following conditions. The maximum applied voltage level was set to 15 kV.

The distance D between the first and second portions 112A and 112B was varied to 0.1 mm, 0.75 mm, 1.5 mm, and 3 mm. At that time, the shortest distance A between the gap 114 and the first portion 112A varies to 5.2 mm, 4.55 mm, 3.8 mm, and 2.3 mm. In a case where the distance D is 0.1 mm, 0.75 mm, or 1.5 mm, the shortest distance A is greater than the distance D.

To be noted, the shortest distance B between the gap 114 and the second portion 112B was set to 5.5 mm, the creeping distance C was set to 2 mm, the length E1, E2, and E3 of each portion of the conductive member 112 were set to 140 mm, and the length F of the edge surface 1031 of the wiring board 103 was set to 122 mm.

While varying the distance D between the first and second portions 112A and 112B, a noise voltage that was superposed onto the wiring pattern 106 of the wiring board 104 was measured with an oscilloscope.

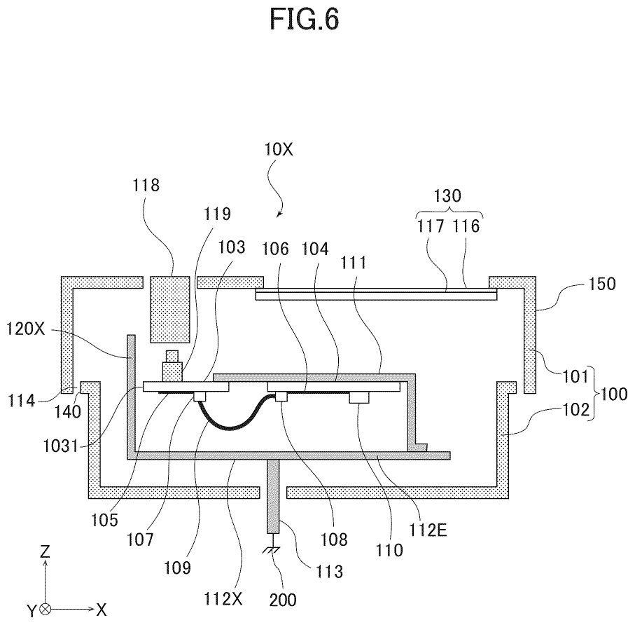

In addition, FIG. 6 is a cross-sectional view illustrating part of electronic equipment of a comparative example. In FIG. 6, a cross-section of an operation unit 10X of the comparative example, serving as a part of the electronic equipment, is illustrated. With respect to the electronic equipment of the comparative example, the electrostatic discharge (air discharge) test was conducted under the following conditions. The maximum applied voltage level was set to 15 kV.

The difference between the operation unit 10X of the comparative example and the operation unit 10 of Example 1 is that a shielding portion 120X of a conductive member 112X is a straight, plate-shaped portion, rather than having the facing configuration of the first and second portions 112A and 112B as in the shielding portion 120 of Example 1. The noise voltage that was superposed onto the wiring pattern 106 of the wiring board 104 of the comparative example was measured with an oscilloscope.

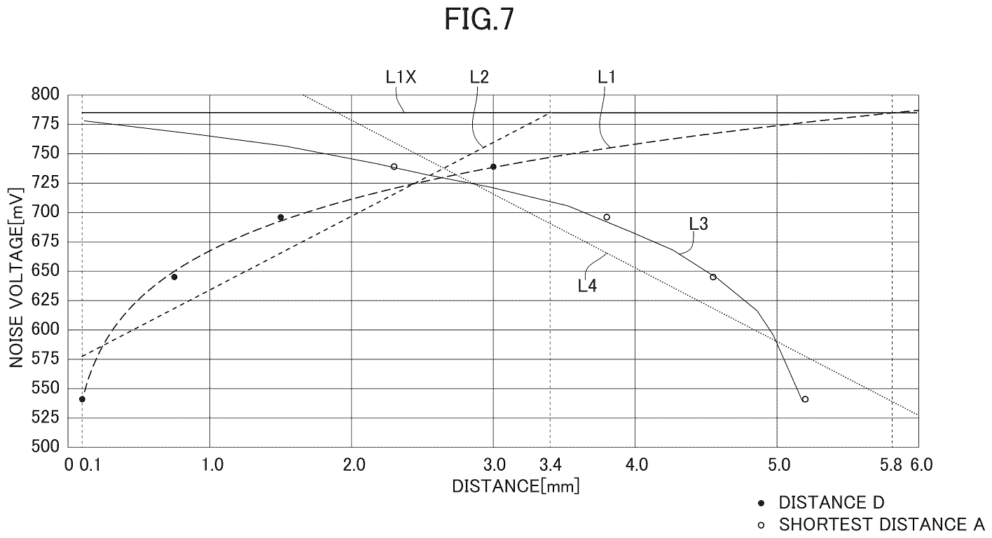

FIG. 7 is a graph illustrating experimental results of Example 1 and the comparative example. In FIG. 7, the horizontal axis indicates distance [mm], and the vertical axis indicates the noise voltage [millivolts (mV)].

In FIG. 7, the results of noise voltage measurements with respect to the distance D for Example 1 are indicated by solid black circles. As illustrated in FIG. 7, as the distance D decreased, the noise voltage was reduced. This is because, as described above, the magnetic field cancellation effect is more enhanced as the distance D decreases. To be noted, a long dashed line L1 illustrated in FIG. 7 indicates a power regression line of the solid black circles, while a short dashed line L2 illustrated in FIG. 7 corresponds to a linear regression line of the solid black circles.

In addition, in FIG. 7, the results of the noise voltage measurements with respect to the distance A for Example 1 are indicated by white-filled black circles. As illustrated n FIG. 7, as the distance A increased, the noise voltage was reduced. To be noted, a solid line L3 illustrated in FIG. 7 indicates a power regression line of the white-filled black circles, while a dashed line L4 in FIG. 7 corresponds to a linear regression line of the white-filled black circles.

In addition, in FIG. 7, the measurement results of the noise voltage for the comparative example are indicated by a solid line LIX.

The solid line LIX and the long dashed line L1 in FIG. 7 intersect at a point at which the distance D between the first and second portions 112A and 112B is 5.8 mm, which exceeds 5.0 mm. In other words, if the distance D between the first and second portions 112A and 112B is preferably equal to or less than 5.8 mm, more preferably equal to or less than 5.0 mm, the magnetic field cancellation effect of the shielding portion 120 of the conductive member 112 arranged in the facing configuration takes effect, and, thereby, it can be said that the noise voltage in the IC 110 is reduced. Therefore, the distance D between the first and second portions 112A and 112B can be equal to or less than 5.8 mm. In addition, the distance D can be equal to or less than 5.0 mm.

In addition, when the distance D between the first and second portions 112A and 112B is 3.4 mm, the solid line L1X and the short dotted line L2 in FIG. 7 intersect. In other words, if the distance D between the first and second portions 112A and 112B is equal to or less than 3.4 mm, the magnetic field cancellation effect of shielding portion 120 of the conductive member 112, which is arranged in the facing configuration, takes effect to reduce the noise voltage in the IC 110. Therefore, the distance D between the first and second portions 112A and 112B can be equal to or less than 3.4 mm.

In addition, in FIG. 7, the solid line LIX and the solid line L3, which indicates the power regression line of the shortest distance A, do not intersect even at a point at which the shortest distance A is 0.1 mm, and, as the shortest distance A increased beyond 0.1 mm, the noise voltage decreased.

The shortest distance A can be equal to or more than 0.1 mm to ensure reliable engagement between the upper and lower covers 101 and 102 even if variations occur during the manufacturing of the enclosure 100. In addition, since the noise voltage decreases as the shortest distance A increases, the shortest distance A can be equal to or greater than 1.0 mm.

In addition, in FIG. 7, the solid line LIX and the dotted line L4, which indicates the linear regression line for the shortest distance A, intersect at a point at which the shortest distance A falls below 2.0 mm. In other words, the shortest distance A can be equal to or greater than 2.0 mm.

In addition, considering the miniaturization of the operation unit 10, the shortest distance A can be equal to or less than 10.0 mm. In addition, the shortest distance A can be equal to or less than 6.0 mm.

### OTHER VARIANT EXAMPLES

This disclosure is not limited to the embodiments described above, and various modifications can be made to the embodiments within the scope of the technical concept of this disclosure. For example, at least two among the plurality of embodiments and plurality of variant examples described above may be combined. In addition, the effects described in the present embodiments only list the most optimal effects generated from the embodiments of this disclosure, and the effects resulting from the embodiments of this disclosure are not limited to those described in the present embodiments.

In the embodiments described above, a case where two wiring boards 103 and 104 are arranged inside the enclosure 100 and the wiring board, which is located closer to the gap 114 between the wiring boards 103 and 104, is the wiring board 103 is described as an example; however, it is not limited to this. For example, the wiring board disposed adjacent to the gap 114 may be the wiring board 104.

In addition, a case where the number of wiring boards arranged inside the enclosure 100 is two is described; however, it is not limited to this. The number of wiring boards arranged inside the enclosure 100 may be one or may be plural. In a case where the number of wiring boards arranged inside the enclosure 100 is one, a single wiring board may be shielded by the shielding portion 120 described in the above embodiments. In addition, in a case where the number of wiring boards arranged inside the enclosure 100 is plural, among a plurality of wiring boards, at least a wiring board closest to the gap 114 may be shielded by the shielding portion 120 described in the above embodiments.

In addition, while the aforementioned embodiments describe cases where the electronic equipment is the office equipment such as the image forming apparatus, it is not limited to this. The electronic equipment is also applicable to imaging equipment such as digital cameras, information equipment such as smartphones, tablets, and personal computers, communication equipment such as modems and routers, medical equipment such as X-ray radiographing apparatuses and endoscopes, industrial equipment such as robots and semiconductor manufacturing apparatuses, and transportation equipment such as vehicles, aircraft, and vessels. In addition, this disclosure is applicable to business equipment such as automated teller machines (ATMs), currency exchange machines, cash registers, and automated vending machines for various goods, including food, beverage, and tickets.

Furthermore, the contents of disclosure in the present specification include not only contents described in the present specification but also all of the items which are understandable from the present specification and the drawings accompanying the present specification. Moreover, the contents of disclosure in the present specification include a complementary set of concepts described in the present specification. Thus, if, in the present specification, there is a description indicating that, for example, “A is B”, even when a description indicating that “A is not B” is omitted, the present specification can be said to disclose a description indicating that “A is not B”. This is because, in a case where there is a description indicating that “A is B”, taking into consideration a case where “A is not B” is a premise.

As described above, this disclosure provides a technique that improves resistance to electrostatic discharge.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-176757, filed Oct. 8, 2024, and Japanese Patent Application No. 2025-150971, filed Sep. 11, 2025, which are hereby incorporated by reference herein in their entirety.

What is claimed is:

1. Electronic equipment comprising:
an enclosure made of resin;
a wiring board arranged inside the enclosure; and
a conductive member arranged inside the enclosure,
wherein the conductive member includes
a portion arranged between a gap of the enclosure and the wiring board, wherein the portion includes:
a first portion with one end in a first direction formed as an open end; and
a second portion that is continuous with another end in the first direction of the first portion,
wherein at least part of the second portion faces the first portion via an insulator in a second direction intersecting with the first direction, and
wherein a first distance that is a shortest distance between the gap of the enclosure and the first portion is less than a second distance that is a shortest distance between the gap of the enclosure and the second portion.

2. The electronic equipment according to claim 1,
wherein the gap is formed in a side wall of the enclosure, and
wherein the first direction is a height direction of the side wall.

3. The electronic equipment according to claim 1,
wherein the enclosure includes a first cover secured to at least the conductive member and a second cover configured to engage with the first cover, and wherein the gap is a gap between the first cover and the second cover.

4. The electronic equipment according to claim 1,
wherein the wiring board includes an edge surface that faces the second portion in the second direction, and
wherein a longitudinal direction of the edge surface is a third direction intersecting with the first direction and the second direction.

5. The electronic equipment according to claim 4,
wherein length of the second portion in the third direction is greater than length of the edge surface of the wiring board in the third direction.

6. The electronic equipment according to claim 4,
wherein length of the first portion in the third direction is greater than length of the edge surface of the wiring board in the third direction.

7. The electronic equipment according to claim 4,
wherein, the first portion overlaps the edge surface of the wiring board in the second direction.

8. The electronic equipment according to claim 1,
wherein the insulator includes air.

9. The electronic equipment according to claim 1,
wherein the insulator includes an insulating member.

10. The electronic equipment according to claim 1,
wherein the first distance is greater than a distance between the first portion and the second portion.

11. The electronic equipment according to claim 1,
wherein the first distance is equal to or greater than 0.1 mm.

12. The electronic equipment according to claim 1,
wherein the first distance is equal to or greater than 1.0 mm.

13. The electronic equipment according to claim 1,
wherein the first distance is equal to or less than 10.0 mm.

14. The electronic equipment according to claim 1,
wherein a distance between the first portion and the second portion is equal to or less than 5.8 mm.

15. The electronic equipment according to claim 1,
wherein a distance between the first portion and the second portion is equal to or less than 3.4 mm.

16. The electronic equipment according to claim 1,
wherein a distance between the first portion and the second portion is equal to or greater than 0.1 mm.

17. The electronic equipment according to claim 1,
wherein the enclosure includes a delineated surface that defines the gap, and
wherein a sum of a creeping distance along the delineated surface and the first distance is equal to or less than 12 mm.

18. The electronic equipment according to claim 1,
wherein a portion in which the first portion and the second portion are continuous is formed by a bending process.

19. The electronic equipment according to claim 1,
further comprising a touch panel display secured to the enclosure.

20. The electronic equipment according to claim 1,
further comprising an actuation unit; and
an operation unit configured to operate the actuation unit,
wherein the operation unit includes the enclosure, the wiring board, and the conductive member,
wherein the actuation unit includes a metallic frame, and
wherein the conductive member is configured to be electrically connected to the frame.

21. The electronic equipment according to claim 1,
wherein the conductive member is a conductive sheet.

22. The electronic equipment according to claim 1,
wherein the conductive member is a member formed on a surface of a resin member.

23. The electronic equipment according to claim 1,
wherein the conductive member is a conductive resin member.
